(19) United States
(12) Patent Application Publication
(10) Pub. No.: US 2026/0188205 A1
(43) Pub. Date: Jul. 2, 2026

(54) DATA PROCESSING METHOD AND DATA PROCESSING APPARATUS

(71) Applicant: Hefei Visionox Technology Co., Ltd., Hefei (CN)

(72) Inventors: Wenyu ZENG, Hefei (CN); Zongzhi CHEN, Hefei (CN); Shundong BAO, Hefei (CN); Jingping ZHANG, Hefei (CN)

(73) Assignee: Hefei Visionox Technology Co., Ltd., Hefei (CN)

(21) Appl. No.: 19/403,193

(22) Filed: Nov. 27, 2025

(30) Foreign Application Priority Data
Dec. 26, 2024 (CN) 202411949390.7

(51) Int. Cl. G09G 3/3225; H10K 59/131

(52) U.S. Cl. CPC G09G 3/3225; H10K 59/131; G09G 2320/0233; G09G 2320/0242; G09G 2320/0626; G09G 2320/0693; G09G 2330/02; G09G 2360/16

(57) ABSTRACT

The present application provide a data processing method and a data processing apparatus. The method may include: obtaining a first mapping relationship between a common voltage and a monochromatic luminance value of the display panel; parsing the first mapping relationship to obtain a second mapping relationship between the common voltage and a monochromatic luminance change rate for the sub-pixels of each color; and determining a target common voltage based on the second mapping relationship to power the display panel with the target common voltage.

### CROSS-REFERENCE TO RELATED APPLICATIONS

The present application claims priority to the Chinese Patent Application 202411949390.7, filed on Dec. 26, 2024, and the entire contents of the aforementioned application are hereby incorporated by reference in its entirety.

### FIELD

The present application relate to the field of display technology, and in particular to a data processing method and a data processing apparatus.

### BACKGROUND

Organic light-emitting diodes (OLEDs) as well as flat panel display devices based on technologies such as light-emitting diodes (LEDs) have been widely applied in various consumer electronics such as mobile phones, televisions, notebook computers, and desktop computers and predominate in display apparatuses thanks to their advantages such as high image quality, energy efficiency, slim design, and wide application range.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN118251982A, CN116648095A, CN117062489A, CN118742138A, CN118678783A, CN118660598A, CN118675450A, CN118824188A, and CN118781966A.

However, the display image quality of current OLED display products still needs improvement.

### SUMMARY

In view of this, embodiments of the present application provide a data processing method, a data processing apparatus, a computer storage medium, a display apparatus, and a display terminal, to at least partially solve the above problem.

According to the embodiments of the present application, a data processing method is provided. The method includes:
obtaining a first mapping relationship between a common voltage and a monochromatic luminance value of the display panel, and sub-pixels of each color in the display panel are individually lit to cause the display panel to present different monochromatic images; parsing the first mapping relationship to obtain a second mapping relationship between the common voltage and a monochromatic luminance change rate for the sub-pixels of each color, the monochromatic luminance change rate representing a speed at which the monochromatic luminance value changes with the common voltage; and
Determining a target common voltage based on the second mapping relationship to power the display panel with the target common voltage, and the monochromatic luminance change rate for the sub-pixels of each color at the target common voltage is less than a preset change rate threshold.

According to embodiments of the present application, a data processing method is provided. The method includes:
obtaining a first mapping relationship between a common voltage corresponding to the sub-pixels of each color and a monochromatic luminance value, and sub-pixels of each color in the display panel are individually lit to cause the display panel to present different monochromatic images;
parsing the first mapping relationship to obtain a second mapping relationship between the common voltage corresponding to the sub-pixels of each color and a monochromatic luminance change rate, the monochromatic luminance change rate representing a speed at which the monochromatic luminance value changes with the common voltage; and determining a target common voltage corresponding to the sub-pixels of each color based on the second mapping relationship to power the sub-pixels of each color in the display panel with the target common voltage corresponding to the sub-pixels of each color, and the monochromatic luminance change rate at sub-pixels of a single color that corresponds to the target common voltage is less than a preset change rate threshold corresponding to the sub-pixels of the single color.

According to embodiments of the present application, a data processing apparatus is provided. The apparatus includes:
an obtaining module configured to obtain a first mapping relationship between a common voltage and a monochromatic luminance value of the display panel, and sub-pixels of each color in the display panel are individually lit to cause the display panel to present different monochromatic images;
a parsing module configured to parse the first mapping relationship to obtain a second mapping relationship between the common voltage and a monochromatic luminance change rate for the sub-pixels of each color, the monochromatic luminance change rate representing a speed at which the monochromatic luminance value changes with the common voltage; and
a determination module configured to determine a target common voltage based on the second mapping relationship to power the display panel with the target common voltage, and the monochromatic luminance change rate at the target common voltage is less than a preset change rate threshold.

According to embodiments of the present application, a computer storage medium is provided. The computer storage medium is configured to store computer program instructions for performing the data processing method in the embodiments.

According to embodiments of the present application, a display apparatus is provided. The display apparatus includes: a display panel, where a one-time programming action is performed on the display panel after power is supplied with the target common voltage obtained according to the method in the embodiments.

According to embodiments of the present application, a display terminal is provided. The display terminal includes a terminal device body and a display apparatus in the embodiments that is disposed on the terminal device body.

Through the data processing solution provided in the embodiments of the present application, when the target common voltage is determined, the first mapping relationship between the common voltage and the monochromatic luminance value of the display panel is obtained in the case where the sub-pixels of each color in the display panel are individually lit. The first mapping relationship is parsed to further obtain the second mapping relationship between the common voltage and the monochromatic luminance change rate corresponding to the sub-pixels of each color. Then, the target common voltage is determined based on the second mapping relationship, where each monochromatic luminance change rate corresponding to the target common voltage is less than the preset change rate threshold.

The display panel is powered with the target common voltage determined according to the solution provided in the embodiments of the present application, and a thin-film transistor driving OLED pixels can still operate in a saturation region even if a voltage value of an actual common voltage applied across two terminals of the display panel exhibits certain fluctuations, ensuring that the monochromatic luminance value of the display panel for the sub-pixels of each color remains almost unchanged. Therefore, the embodiments of the present application can improve the display image quality of the display panel.

### BRIEF DESCRIPTION OF THE DRAWINGS

To illustrate the embodiments of the present application more clearly, a brief introduction to the drawings to be used in the description of the embodiments will be made below. The drawings in the following description are merely some of the embodiments of the embodiments of the present application.

FIG. 1a is a schematic structural diagram of a display panel in the related art;

FIG. 1b is a schematic diagram of a circuit structure of a display panel in the related art;

FIG. 2 is a schematic flowchart of a data processing method according to an embodiment of the present application;

FIG. 3 is a schematic flowchart of a one-time programming process performed based on a data processing method according to an embodiment of the present application;

FIG. 4 is a common voltage-monochromatic luminance value curve plotted;

FIG. 5 is a common voltage-monochromatic luminance change rate curve plotted;

FIG. 6 is another schematic flowchart of a one-time programming process performed based on a data processing method according to an embodiment of the present application;

FIG. 7 is a schematic diagram of a first curve between a common voltage and a monochromatic luminance value of a display panel;

FIG. 8 is a schematic structural diagram of a data processing apparatus according to an embodiment of the present application; and

FIG. 9 is a schematic structural diagram of a display terminal according to an embodiment of the present application;

FIG. 10 is a schematic flowchart of another data processing method according to an embodiment of the present application; and

FIG. 11 is a schematic structural diagram of a display panel in the related art.

### DETAILED DESCRIPTION OF THE EMBODIMENTS

To enable better understand the embodiments of the present application, the embodiments of the present application will be clearly and completely described below with reference to the drawings in the embodiments of the present application. The described embodiments are merely some, rather than all, of the embodiments of the present application.

The terms used in the embodiments of the present application are merely for the purpose of describing specific embodiments, and are not intended to limit the present application. The terms “a/an”, “said”, and “the” of singular forms used in the embodiments and the appended claims of the present application are also intended to include plural forms, unless otherwise specified in the context clearly. It should also be understood that the term “and/or” used in the embodiments of the present application refers to and includes any or all possible combinations of one or more associated items listed.

In the following description, the phrase “some embodiments” is involved, which describe a subset of all possible embodiments. However, it may be understood that the phrase “some embodiments” may be the same subset or different subsets of all the possible embodiments, and may be combined with each other without conflicts.

It should also be noted that the terms “first\second\third” involved in the embodiments of the present application are only intended to distinguish between similar objects and do not represent a particular order of the objects. It may be understood that particular sequences or sequential orders indicated by the terms “first/second/third” may be interchanged if permitted, and the embodiments of the present application described herein can be implemented in an order other than that illustrated or described herein.

Furthermore, the term “and/or” in the embodiments of the present application is merely the description of an association relationship between associated objects, and indicates that three relationships may exist. For example, A and/or B may indicate that: only A exists, both A and B exist, and only B exists. In addition, the character “/” herein generally indicates an “or” relationship between associated objects before and after it.

In order to facilitate understanding of the embodiments of the present application, technologies related to the embodiments of the present application are described below. The following related technologies may be randomly combined, as some embodiments, with the embodiments of the present application, and all fall within the scope of protection of the embodiments of the present application.

Organic light-emitting diodes (OLEDs) as well as flat panel display devices based on technologies such as light-emitting diodes (LEDs) have been widely applied in various consumer electronics such as mobile phones, televisions, notebook computers, and desktop computers and predominate in display apparatuses thanks to their advantages such as high image quality, energy efficiency, slim design, and wide application range.

Referring to FIG. 1a, in order to improve product performance, in a novel OLED display technology, a display panel may include: a substrate 1; a pixel defining layer 2 disposed on the substrate 1, the pixel defining layer 2 including a pixel defining portion and pixel openings defined by the pixel defining portion; an isolation structure 3 located on a side of the substrate 1, the isolation structure enclosing isolation openings, the isolation opening being in communication with the pixel opening; and a light-emitting unit 4 located within the isolation opening, the light-emitting unit 4 including an anode 41, a light-emitting functional layer 42, and a cathode 43 arranged in sequence, at least part of the cathode 43 being coupled with the isolation structure 3, and the isolation structure 3 is a conductive material for transmitting a common voltage to the cathode 43.

A cathode potential of the display panel is jointly determined by a common voltage ELVSS and a cathode coupling impedance. Referring to FIG. 1b, compared with a conventional drive circuit and the light-emitting unit prepared by the FMM process, a drive circuit corresponding to the novel technology is additionally coupled with a cathode impedance R. Moreover, a corresponding process flow is performed independently for sub-pixels of each color. The specific flow includes: performing an evaporation operation for B color sub-pixels, performing a patterning operation for the B color sub-pixels→performing an evaporation operation for G color sub-pixels, performing a patterning operation for the G color sub-pixels→performing an evaporation operation for R color sub-pixels, and performing a patterning operation for the R color sub-pixels. And the B color, G color, R color indicate that the prepared light-emitting unit can emit blue light, green light and red light respectively.

Since the above process is performed independently for sub-pixels of each color, the sub-pixels of each color are coupled with respective cathode impedances. In the process of implementing the present disclosure, the inventors have found that the following problem is present in the related art: the display image quality of the display panel is poor.

Prior to detailed description of the embodiments of the present application, the execution timing of the embodiments of the present application is first briefly described.

Luminance of an OLED display panel is controlled by a gate voltage of a thin-film transistor driving OLED pixels. The OLED pixels have varying luminance under different gate voltages. In order to ensure consistency and accuracy of display results, during the manufacturing of an OLED module, it is necessary to perform luminance calibration for each pixel, and to store calibration data using a one-time programmable (OTP) memory technology. That is, in order to improve a display effect, during the manufacturing of the OLED module, it is necessary to perform an OTP process operation to program and store pixel luminance values corresponding to different pixel luminance levels and corresponding thin-film transistor gate voltages.

Prior to the OTP process operation, it is usually necessary to perform programming environment configuration. That is, for each pixel luminance level, a specific common voltage value to be applied to the display panel during the OTP process operation is determined. After the common voltage value is determined, the subsequent OTP process operation may specifically include: adjusting a specific value of a thin-film transistor gate voltage, and a pixel luminance value of the OLED display panel satisfies a luminance value requirement of the pixel luminance level; and then programming and storing a correspondence between the adjusted thin-film transistor gate voltage value and the pixel luminance level.

The data processing method provided in the embodiments of the present application is mainly used for determining, for each pixel luminance level prior to the OTP process operation, a specific common voltage value to be applied to the display panel during the OTP process operation. That is, the data processing method provided in the embodiments of the present application is mainly used for determining the programming environment configuration prior to OTP.

The specific implementations of the embodiments of the disclosure are further described below with reference to the drawings of the embodiments of the disclosure.

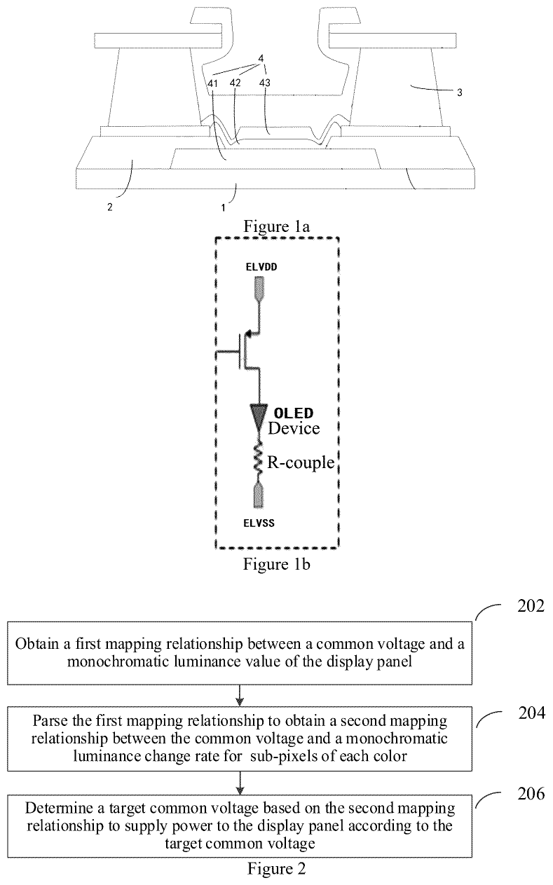

Referring to FIG. 2, FIG. 2 is a schematic flowchart of a data processing method according to an embodiment of the present application. The data processing method of this embodiment includes the following steps.

Step 202: Obtain a first mapping relationship between a common voltage and a monochromatic luminance value of the display panel, and sub-pixels of each color in the display panel are individually lit to cause the display panel to present different monochromatic images.

The display panel in this embodiment of the present application includes sub-pixels of colors, such as R color sub-pixels, G color sub-pixels, and B color sub-pixels, and the sub-pixels of the colors all correspond to the same common voltage. That is, the sub-pixels of the colors in the display panel in this embodiment of the present application share the same common voltage for power supply.

The first mapping relationship in this embodiment of the present application is used for representing a value change relationship between the common voltage and the monochromatic luminance value of the display panel. The specific representation form of the first mapping relationship is not limited in this embodiment of the present application. For example, the first mapping relationship may be represented in the form of a table of value pairs, in the form of a curve, or in the form of a function expression, or the like.

For example, in terms of representation by value pairs, assuming that a monochromatic luminance value of the R color sub-pixels is L1 when the common voltage of the display panel is A1, the monochromatic luminance value of the R color sub-pixels becomes L2 when the common voltage is A2, and the monochromatic luminance value of the R color sub-pixels becomes L3 when the common voltage is A3, the first mapping relationship in this step may be represented in the form of a table of value pairs as follows:

| Common voltage of the display panel | Monochromatic luminance value |
|---|---|
| A1 | L1 |
| A2 | L2 |
| A3 | L3 |

In terms of representation by a curve, the common voltage of the display panel may be set as an x-axis and the monochromatic luminance value to may be set as a y value, or the common voltage of the display panel may be set as a y-axis and the monochromatic luminance value may be set as an x value. Then, a first curve representing the first mapping relationship is obtained by fitting and plotting based on (x, y) coordinate points.

In terms of representation by a function expression, the common voltage of the display panel may be set as an independent variable, and the monochromatic luminance value may be set as a dependent variable, to generate a function expression to represent the first mapping relationship.

Step 204: Parse the first mapping relationship to obtain a second mapping relationship between the common voltage and a monochromatic luminance change rate corresponding to the sub-pixels of each color.

The monochromatic luminance change rate represents a speed at which the monochromatic luminance value changes with the common voltage.

After the mapping relationship between the common voltage and the monochromatic luminance value of the display panel is obtained, the mapping relationship may be parsed to further obtain the mapping relationship between the common voltage and the monochromatic luminance change rate. For ease of distinguishing, in this embodiment of the present application, the mapping relationship between the common voltage and the monochromatic luminance value of the display panel is referred to as the first mapping relationship, and the mapping relationship between the common voltage and the monochromatic luminance change rate is referred to as the second mapping relationship.

The specific manner of obtaining the second mapping relationship is not limited in this embodiment of the present application, and any suitable manner may be custom-selected based on actual situations. For example, for the first mapping relationship represented in the manner of a table of value pairs, curve fitting may be performed based on value pairs, thereby obtaining a change curve between the common voltage and the monochromatic luminance change rate. Then, the second mapping relationship may be obtained by collecting statistics on slopes of the curve at different common voltages. For the first mapping relationship represented in the manner of a curve, the second mapping relationship may be obtained by directly collecting statistics on slopes of the curve at different common voltages. For the first mapping relationship represented in the manner of a function expression, the second mapping relationship may be obtained through a derivative operation on the common voltage as an independent variable.

Step 206: Determine a target common voltage based on the second mapping relationship to power the display panel with the target common voltage.

The monochromatic luminance change rate corresponding to the target common voltage is less than a preset change rate threshold.

After the mapping relationship between the common voltage and the monochromatic luminance change rate is obtained, this step involves parsing the mapping relationship to find a common voltage corresponding to a relatively slow monochromatic luminance change, and then determining the common voltage as the target common voltage. That is, when the common voltage takes a voltage value near the target common voltage, a corresponding monochromatic luminance value exhibits a small change. For example, a change rate of a monochromatic luminance value corresponding to each common voltage within a target common voltage range needs to be less than 3%, in which case an average or a minimum value within the target common voltage range is used as the target common voltage. Ideally, the target common voltage range is such that a change rate corresponding to the common voltage is 0, in which case the target common voltage range is determined and the thin-film transistor driving the OLED pixels operates in a saturation region, thereby ensuring display uniformity.

From the above analysis, it can be seen that: through step 206, after the target common voltage is determined, when the display panel is powered with the target common voltage as a reference value, even if a voltage value of an actual common voltage fluctuates around the target common voltage, the monochromatic luminance value of the display panel for the sub-pixels of each color can still remain almost unchanged. In this case, the thin-film transistor driving the OLED pixels operates in the saturation region.

In terms of the display panel using the drive circuit shown in FIG. 1, as described above, since the process is performed independently for the sub-pixels of each color, the sub-pixels of each color are coupled with respective cathode impedances. Moreover, due to factors such as the level of the fabrication process, the cathode impedance coupling corresponding to sub-pixels of various colors may vary, which may cause: when the same common voltage ELVSS is used for power supply, actual common voltage values corresponding the sub-pixels of various colors may also exhibit certain fluctuations. For the above case, the common voltage ELVSS (i.e., the target common voltage in this embodiment of the present application) is determined through the solution provided in this embodiment of the present application. Based on the determined common voltage ELVSS, even if the voltage value of the actual common voltage fluctuates around the target common voltage, the thin-film transistor driving the OLED pixels can still operate in the saturation region, ensuring that the monochromatic luminance value of the display panel for the sub-pixels of each color remains almost unchanged, thereby improving the display image effect.

Through the data processing solution provided in this embodiment of the present application, when the target common voltage is determined, the first mapping relationship between the common voltage and the monochromatic luminance value of the display panel for the sub-pixels of each color is obtained. The first mapping relationship is parsed to further obtain the second mapping relationship between the common voltage and the monochromatic luminance change rate corresponding to the sub-pixels of each color. Then, the target common voltage is determined based on the second mapping relationship, where each monochromatic luminance change rate corresponding to the target common voltage is less than the preset change rate threshold. The display panel is powered with the target common voltage determined according to the solution provided in the embodiments of the present application, and a thin-film transistor driving OLED pixels can still operate in a saturation region even if a voltage value of an actual common voltage applied across two terminals of the display panel exhibits certain fluctuations, ensuring that the monochromatic luminance value of the display panel for the sub-pixels of each color remains almost unchanged. Therefore, the embodiments of the present application can improve the display image quality of the display panel.

In some embodiments, the obtaining a first mapping relationship between a common voltage and a monochromatic luminance value of the display panel includes:
determining, for different display modes of the display panel, a theoretical common voltage value of the display panel and determining a common voltage calibration range based on the theoretical common voltage value; and
selecting and determining one of the display modes as a current display mode, and in the current display mode, sub-pixels of each color in the display panel are individually lit to cause the display panel to present different monochromatic images, obtaining the first mapping relationship between the common voltage and the monochromatic luminance value of the display panel within the common voltage calibration range.

The determining a target common voltage based on the second mapping relationship to power the display panel with the target common voltage includes:
Determining the target common voltage within the common voltage calibration range based on the second mapping relationship, to power the display panel with the target common voltage.

The target common voltage is stored in the display panel through a programming action.

Regardless of fluctuations in the actual common voltage value caused by the fabrication process, for each display mode, there is a corresponding common voltage value of the display panel. That is, regardless of the fluctuations in the actual common voltage value, in order for the pixel luminance of the display panel to satisfy a requirement of a specific display mode, a common voltage value to be applied to the display panel is a fixed value that can be obtained through theoretical analysis or empirical deduction, i.e., the theoretical common voltage value in this embodiment of the present application.

In this embodiment of the present application, the theoretical common voltage value may be determined in any suitable manner. For example, the theoretical common voltage value may be determined based on historical calibration experience, in the manner of simulation analysis, or in the manner of experimentation, or the like.

In this embodiment of the present application, during the calibration and searching for the target common voltage value, a common voltage calibration range where the target common voltage most likely to appear is first determined using the theoretical common voltage value as a reference, and then the calibration and searching are performed within this common voltage calibration range. In this way, the target common voltage satisfying the requirement can be quickly and efficiently calibrated with a relatively small amount of data calculation. That is, the above embodiment of the present application can effectively improve the efficiency of determining the target common voltage.

In some embodiments, the first mapping relationship and the second mapping relationship are each represented in the form of a curve.

The obtaining the first mapping relationship between the common voltage and the monochromatic luminance value of the display panel within the common voltage calibration range includes:
performing voltage value sampling within the common voltage calibration range according to a preset voltage sampling rule to obtain sampled common voltages; Obtaining, for each sampled common voltage, a monochromatic luminance value for the sub-pixels of each color at each sampled common voltage; and
Performing curve fitting based on each sampled common voltage and the monochromatic luminance value for the sub-pixels of each color to obtain a first curve as the first mapping relationship between the common voltage and the monochromatic luminance value of the display panel.

Specifically, in the above embodiment of the present application, the first mapping relationship between the common voltage and the monochromatic luminance value of the display panel is represented in the manner of a first curve. Since the first curve is obtained through data sampling and data fitting, it allows for a more intuitive and fine-grained observation of the monochromatic luminance value at any common voltage value, while ensuring the accuracy of the first mapping relationship.

During voltage value sampling within the common voltage calibration range, a reset voltage value connected to an anode of the sub-pixels needs to be adjusted synchronously, with an adjustment magnitude being the same as a change magnitude in the common voltage. For example, when the common voltage is increased by 0.1 V, the corresponding reset voltage value is also increased by 0.1 V. This ensures that a voltage difference between the anode and a cathode of the sub-pixels is less than a turn-on voltage of the light-emitting unit, avoiding an impact on a light-emitting effect of the sub-pixels. The corresponding reset voltage value of the sub-pixels of each color adopt the same reference reset voltage.

The specific content of the voltage sampling rule is not limited in this embodiment of the present application, and may be customized based on actual situations. For example, sampled common voltages are randomly selected from the common voltage calibration range for subsequent operations. In one embodiment, voltage value sampling at a higher density may be performed near the theoretical common voltage value, while voltage value sampling at a lower density may be performed in another region away from the theoretical common voltage value, and so on.

In some embodiments, the preset voltage sampling rule may include: performing voltage value sampling with a preset step within the common voltage calibration range.

The manner of performing voltage value sampling with a uniform step within the common voltage calibration range can ensure a uniform distribution of sampling points across the entire common voltage calibration range, thereby facilitating obtaining of a high-quality dataset. Moreover, the uniform-step sampling method is simple and easy to implement, readily automatable, and suitable for large-scale data acquisition. In addition, since a spacing between sampling points is fixed, data consistency can be ensured, facilitating subsequent data processing and analysis.

In some embodiments, the process of parsing the first mapping relationship to obtain a second mapping relationship between the common voltage and a monochromatic luminance change rate for the sub-pixels of each color include:

In the first curve, calculating the monochromatic luminance change rate at each sampled common voltage based on a voltage difference between two adjacent sampled common voltages and a corresponding monochromatic luminance difference at the two adjacent sampled common voltages; and performing curve fitting based on each sampled common voltage and the monochromatic luminance change rate at each sampled common voltage to obtain a second curve as the second mapping relationship between the common voltage and the monochromatic luminance change rate.

The process of determining the target common voltage within the common voltage calibration range based on the second mapping relationship may specifically include:
Obtaining a preset change rate threshold corresponding to the sub-pixels of each color; and determining whether the monochromatic luminance change rate at each sampled common voltage is less than the preset change rate threshold to obtain determination results, and determining the target common voltage from each sampled common voltage based on a determination result. The determination results are derived from the determining process of all color sub-pixels, and each color sub-pixel may obtain one or more determination results.

The process of determining whether the monochromatic luminance change rate at each sampled common voltage is less than the preset change rate threshold, and determining the target common voltage from each sampled common voltage based on a determination result may include: for the sub-pixels of each color, sequentially calculating a monochromatic luminance change rate at the sampled common voltages according to an ascending order of the sampled common voltages (ignoring plus and minus signs of voltage values and considering only magnitudes of absolute values of the voltages); determining whether the calculated monochromatic luminance change rate is less than the preset change rate threshold; when a sampled common voltage satisfying the above monochromatic luminance change rate condition is determined, determining the sampled common voltage as a candidate common voltage corresponding to the sub-pixels of the color, and stopping the calculation process for the remaining sampled common voltages; and after the candidate common voltages corresponding to the sub-pixels of each color are obtained, determining the candidate common voltage having a minimum value (i.e., the common voltage having a maximum absolute value) among the candidate common voltages as the final target common voltage of the display panel. In this embodiment of the present application, the preset change rate threshold may be a value that is set empirically, a value calculated through a simulation model, or a value obtained by performing product sampling from historical products or historical products in the same batch and performing data statistics collection. A specific manner of determining the preset change rate threshold and a specific value of the preset change rate threshold are not limited in this embodiment of the present application.

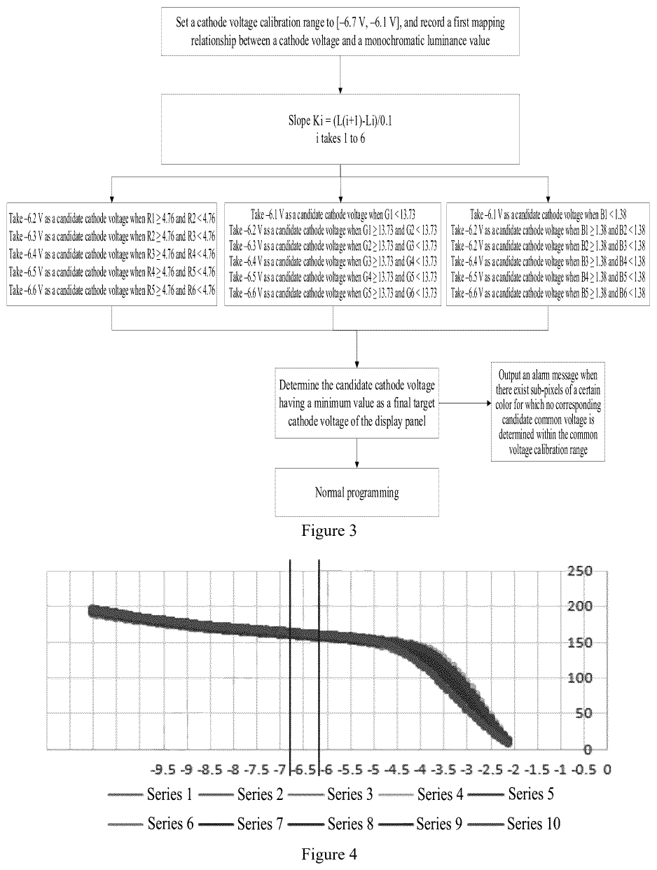

Referring to FIG. 3, FIG. 3 is a schematic flowchart of a one-time programming process performed based on a data processing method according to an embodiment of the present application. A data processing process in the above embodiment of the present application is briefly described below with reference to FIG. 3.

Assuming that the common voltage calibration range is determined to be [−6.7 V, −6.1 V], the first mapping relationship between the common voltage and the monochromatic luminance value of the display panel within the common voltage calibration range can be recorded, respectively, when the sub-pixels of each color are individually lit.

Then, within the common voltage calibration range, voltage value sampling may be performed with a sampling step of 0.1 V, to obtain six sampled common voltages: −6.1 V, −6.2 V, −6.3 V, −6.4 V, −6.5 V, and −6.6 V. The monochromatic luminance change rate at each sampled common voltage is calculated based on the voltage difference between two adjacent sampled common voltages and the corresponding monochromatic luminance difference at the two adjacent sampled common voltages, and the mapping relationship between each sampled common voltage and the monochromatic luminance change rate at each sampled common voltage is determined as the second mapping relationship between the common voltage and the monochromatic luminance change rate. Correspondingly, a calculation formula is:

$${K}_{i} = ( {L}_{( i + 1 )} - {L}_{i} ) / 0.1$$

where Kᵢ is a slope value (monochromatic luminance change rate) at an i^{th} sampled common voltage; and Lᵢ is a corresponding monochromatic luminance value at the i^{th} sampled common voltage, L₍ᵢ₊₁₎ a corresponding monochromatic luminance value at the i^{th}+1 sampled common voltage.

According to an order from −6.1 V to −6.6 V, the monochromatic luminance change rate at each sampled common voltage is sequentially determined for the sub-pixels of each color using the above formula. In addition, it is assumed that for the R, G, and B color sub-pixels, the preset change rate thresholds obtained are 4.76, 13.73, and 1.38, respectively (the manner of obtaining the preset change rate thresholds will be explained and described with reference to FIG. 4 in the subsequent section). As shown in FIG. 3, for the R color sub-pixels, when R1 (the monochromatic luminance change rate at −6.1 V)≥4.76 and R2 (the monochromatic luminance change rate at −6.2 V)<4.76, −6.2 V is used as the candidate common voltage corresponding to the R color sub-pixels. Otherwise, when R2 (the monochromatic luminance change rate at −6.2 V)≥4.76 and R3 (the monochromatic luminance change rate at −6.3 V)<4.76, −6.3 V is used as the candidate common voltage corresponding to the R color sub-pixels. The process is repeated in the same manner until the value of R6 (the monochromatic luminance change rate at −6.6 V) is calculated. Similarly, for the G color sub-pixels, when G1 (the monochromatic luminance change rate at −6.1 V)<13.73, −6.1 V is used as the candidate common voltage corresponding to the G color sub-pixels. Otherwise, when G1 (the monochromatic luminance change rate at −6.1 V)≥13.73 and G2 (the monochromatic luminance change rate at −6.2 V)<13.73, −6.2 V is used as the candidate common voltage corresponding to the G color sub-pixels. Otherwise, when G2 (the monochromatic luminance change rate at −6.2 V)≥13.73 and G3 (the monochromatic luminance change rate at −6.3 V)<13.73, −6.3 V is used as the candidate common voltage corresponding to the G color sub-pixels. The process is repeated in the same manner until the value of G6 (the monochromatic luminance change rate at −6.6 V) is calculated. Similarly, for the B color sub-pixels, when B1 (the monochromatic luminance change rate at −6.1 V)<1.38, −6.1 V is used as the candidate common voltage corresponding to the B color sub-pixels. Otherwise, when B1 (the monochromatic luminance change rate at −6.1 V)≥1.38 and B2 (the monochromatic luminance change rate at −6.2 V)<1.38, −6.2 V is used as the candidate common voltage corresponding to the B color sub-pixels. Otherwise, when B2 (the monochromatic luminance change rate at −6.2 V)≥1.38 and B3 (the monochromatic luminance change rate at −6.3 V)<1.38, −6.3 V is used as the candidate common voltage corresponding to the B color sub-pixels. The process is repeated in the same manner until the value of B6 (the monochromatic luminance change rate at −6.6 V) is calculated.

After the candidate common voltages corresponding to the sub-pixels of each color are obtained, the candidate common voltage having a minimum value (i.e., the candidate common voltage having a maximum absolute value) among the candidate common voltages may be determined as the final target common voltage of the display panel, and the determined target common voltage may be stored in the display panel through a programming action. For example, as shown in FIG. 3, assuming that the candidate common voltage corresponding to the R color sub-pixels is −6.5 V, the candidate common voltage corresponding to the G color sub-pixels is −6.2 V, and the candidate common voltage corresponding to the B color sub-pixels is −6.3 V, the final target common voltage of the display panel may be determined to be −6.5 V.

In addition, when there exist sub-pixels of a certain color (i.e., the R color sub-pixels, the G color sub-pixels, or the B color sub-pixels) for which no corresponding candidate common voltage is determined within the common voltage calibration range by means of the sequential determination, it is considered that an abnormality exists in the cathode coupling corresponding to the sub-pixels of this color, and an alarm message may be output in this case.

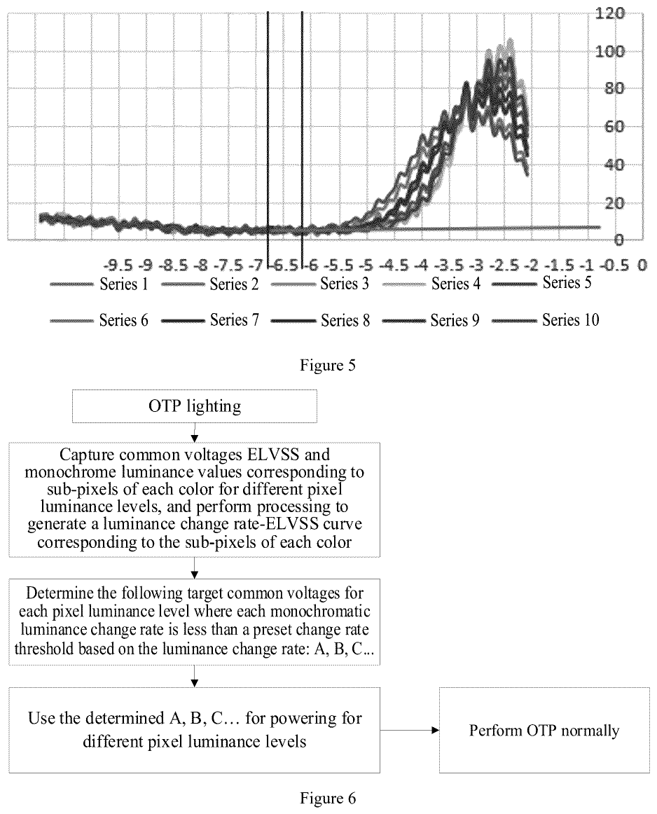

The manner of obtaining the preset change rate threshold is described below with reference to FIG. 4 and FIG. 5. As shown in FIG. 4, before the solution of this embodiment of the present application is performed on the display panel, product sampling may be first performed from products in the same batch as the display panel by means of sampling. For example, taking the R color sub-pixels as an example, ten display panels are sampled in FIG. 4, and common voltage-monochromatic luminance value curves are plotted for the ten display panels, the curves of different colors in the figure correspond to different display panels. Then, based on the curves, an interval having a relatively small slope is determined as the common voltage calibration range (−6.1 V to −6.7 V). Further, a common voltage-monochromatic luminance change rate (i.e., slope) curve may be plotted based on the common voltage-monochromatic luminance value curves (referring to FIG. 5). Then, based on slope values of the display panels within the common voltage calibration range, a preset change rate threshold corresponding to the R color sub-pixels is obtained through fusion. The fusion process includes, but is not limited to, taking an average of the sampled slopes.

In some embodiments, the display panel has display modes, and any of the display modes has pixel luminance levels of the display panel.

For the different pixel luminance levels to be programmed in the display mode, the step of determining a theoretical common voltage value of the display panel and determining a common voltage calibration range based on the theoretical common voltage value is performed, until a target common voltage for each pixel luminance level in each display mode is determined.

The pixel luminance supported by the display panel is usually divided into different pixel luminance levels, with each level corresponding to a specific pixel luminance value. For example, for a display panel supporting a luminance of 600 nit, six pixel luminance levels may be set: BAND1—100 nit, BAND2—200 nit, BAND3—300 nit, BAND4—400 nit, BAND5—500 nit, and BAND6—600 nit. Then, during an OTP action, a target common voltage may be determined for each pixel luminance level, and the pixel luminance level and the corresponding target common voltage may be programmed and stored.

In the above embodiment of the present application, for each pixel luminance level, the operations of step 202 to step 206 are performed, thereby obtaining the target common voltage corresponding to each pixel luminance level. In the above process, for each pixel luminance level, the target common voltage satisfying the requirement of the monochromatic luminance change rate is accurately determined from the perspective of the monochromatic luminance change rate. Therefore, the above embodiment of the present application can ensure the accuracy of the common target voltage finally obtained, thereby further improving the display image quality.

In some embodiments, the display panel has display modes, and any of the display modes has pixel luminance levels of the display panel.

The determining, for different display modes of the display panel, a theoretical common voltage value of the display panel and determine a common voltage calibration range based on the theoretical common voltage value includes:
selecting a reference pixel luminance level from the pixel luminance levels of the display panel;
for the reference pixel luminance level, performing the step of determining a theoretical common voltage value of the display panel and determining a common voltage calibration range based on the theoretical common voltage value, until a target common voltage for the reference pixel luminance level is determined; and
calculating target common voltages for remaining levels of the pixel luminance levels based on the target common voltage for the reference pixel luminance level and an association relationship between target common voltages corresponding to different pixel luminance levels.

Unlike the above embodiment, this embodiment does not involve performing the operations of step 202 to step 206 for each pixel luminance level, but involves determining a reference pixel luminance level from levels, followed by performing step 202 to step 206 only for this reference pixel luminance level, thereby obtaining the target common voltage corresponding to the reference pixel luminance level. For the other levels, target common voltages for the other levels are calculated based on the target common voltage corresponding to the reference pixel luminance level using the association relationship between the target common voltages corresponding to different pixel luminance levels.

The above process effectively reduces the total time consumed by the process of determining the target common voltages, thereby shortening the production cycle of the product and further effectively improve the production efficiency.

In this embodiment of the present application, any of the pixel luminance levels may be determined as the reference pixel luminance level, and the specific manner of selecting the reference pixel luminance level is not limited. In addition, the association relationship between the target common voltages corresponding to different pixel luminance levels may be obtained through simulation, obtained empirically, or the like. In this embodiment of the present application, the specific manner of obtaining the association relationship between the target common voltages corresponding to different pixel luminance levels is also not limited, and may be custom-selected based on actual situations.

In some embodiments, the calculating target common voltages for remaining levels of the pixel luminance levels based on the target common voltage for the reference pixel luminance level and an association relationship between target common voltages corresponding to different pixel luminance levels includes:
determining that each of the remaining levels corresponds to a first theoretical common voltage value, and that the reference pixel luminance level corresponds to a second theoretical voltage value;
calculating a theoretical voltage difference between the first theoretical common voltage value and the second theoretical voltage value;
calculating a target common voltage corresponding to each of the remaining levels based on the target common voltage of the reference pixel luminance level and the theoretical voltage difference corresponding to each of the remaining levels.

In one embodiment, based on properties of the display panel, the differences between the corresponding common voltage values for different pixel luminance levels are usually relatively stable. Therefore, in the above embodiment of the present application, after the target common voltage for the reference pixel luminance level is obtained, a specific difference between common voltage values corresponding to different pixel luminance levels is calculated based on a theoretical common voltage value corresponding to each pixel luminance level. Then, the target common voltage for the reference pixel luminance level may be used as a reference value, and the reference value may be adjusted based on each voltage difference, thereby quickly and efficiently obtaining the target common voltages for the other levels. The above embodiment can effectively improve the efficiency of determining the target common voltage, thereby shortening the production cycle of the display panel and improving the production efficiency.

In some embodiments, a process of determining the theoretical common voltage value of the display panel for each pixel luminance level includes:
constructing a simulation model corresponding to the display panel;
performing a parameter assignment operation on the simulation model based on a pixel luminance value corresponding to each pixel luminance level and material properties of light-emitting layers of the display panel; and
performing simulation calculation based on the simulation model subjected to parameter assignment, to obtain the theoretical common voltage value corresponding to each pixel luminance level.

In the above embodiment, after the simulation model corresponding to the display panel is constructed, the parameter assignment operation is performed on the simulation model based on the pixel luminance value corresponding to the pixel luminance level and the material property of the light-emitting layer of the display panel, and the simulation model can more accurately represent the properties of the display panel, thereby finally obtaining a theoretical common voltage value with higher accuracy. In addition, since the simulation calculation process does not require a physical device for calibration, the above embodiment of the present application can also improve the efficiency of calculating the theoretical common voltage value.

In some embodiments, the data processing method may further include:

outputting display performance warning information when no target common voltage satisfying a requirement exists within the common voltage calibration range based on the second mapping relationship.

In each of the above plurality of embodiments of the present application, the discussion is carried out with the presence of a target common voltage within the common voltage calibration range. However, when the process results in a significant difference in the cathode impedance coupling corresponding to the sub-pixels of each color, it is possible that no target common voltage satisfying the requirement can be found within the common voltage calibration range. In this embodiment, the display performance of the display panel is usually poor. For the above reason, in order to promptly find a display panel with substandard performance, in this embodiment of the present application, when no target common voltage satisfying the requirement exists within the common voltage calibration range, the display performance warning information may be output to facilitate subsequent operations (processing such as analysis and discarding) on the product with substandard performance.

In some embodiments, the determining a target common voltage based on the second mapping relationship includes:
determining candidate common voltages based on the second mapping relationship, where each monochromatic luminance change rate at the candidate common voltage is less than the preset change rate threshold; and
Determining the candidate common voltage having a minimum absolute value as the target common voltage.

In one embodiment, within a common voltage calibration range for monochromatic display, there are usually common voltages that can satisfy a requirement of a monochromatic luminance change rate (e.g., all common voltage values within a specific target cathode range within the common voltage tuning range may satisfy the requirement). For this case, in this embodiment of the present application, a common voltage having a minimum absolute value is determined as the target common voltage, which can reduce power consumption of the module while improving the display image quality.

In some embodiments, the preset change rate threshold is correspondingly set for the sub-pixels of each color. A monochromatic luminance change rate corresponding to the target common voltage for sub-pixels of a single color is less than a preset change rate threshold for the sub-pixels of the single color.

In the above embodiment of the present application, during the calibration and searching for the target common voltage value, a preset change rate threshold is independently set for the sub-pixels of each color. That is, a corresponding change rate threshold is separately set for the sub-pixels of each color. In the above manner of setting the change rate threshold, differences in display features among the sub-pixels of each color are fully considered, a more accurate target common voltage can be obtained.

For different candidate common voltages corresponding to sub-pixels of different colors, the candidate common voltage having a maximum absolute value is stored to ensure that the luminous intensity of all pixels satisfies a requirement.

For example, when the candidate common voltage for the R color sub-pixels is −6.2 V, the candidate common voltage for the G color sub-pixels is −6.1 V, and the candidate common voltage for the B color sub-pixels is −6.3 V, −6.3 V is selected for storage and confirmed as the common voltage for the current luminance level.

Referring to FIG. 6, FIG. 6 is another schematic flowchart of a one-time programming process performed based on a data processing method according to an embodiment of the present application. A data processing process in this embodiment of the present application is briefly described below with reference to FIG. 6.

During the manufacturing of the display panel, an OTP lighting operation is first performed. In one embodiment, a lighting test mainly aims to verify whether each pixel in the display panel can normally emit light. This process usually involves applying a current to the display panel to check whether any pixel exhibits a fault or luminance inconsistency.

After the OTP lighting operation, a data capture operation may be performed. The value of the corresponding common voltage ELVSS is captured when the pixel luminance reaches each pixel luminance level, and a luminance change rate-common voltage ELVSS curve corresponding to the sub-pixels of each color is generated based on the captured data.

Based on the luminance change rate, the following target common voltages for each pixel luminance level where each monochromatic luminance change rate is less than the preset change rate threshold are determined based on the above curve: A, B, C . . .

For the different pixel luminance levels, the determined A, B, C . . . are used to power the display panel, thereby performing the normal OTP process operation.

For ease of understanding, the data processing process provided in this embodiment of the present application is explained and described below by way of specific examples.

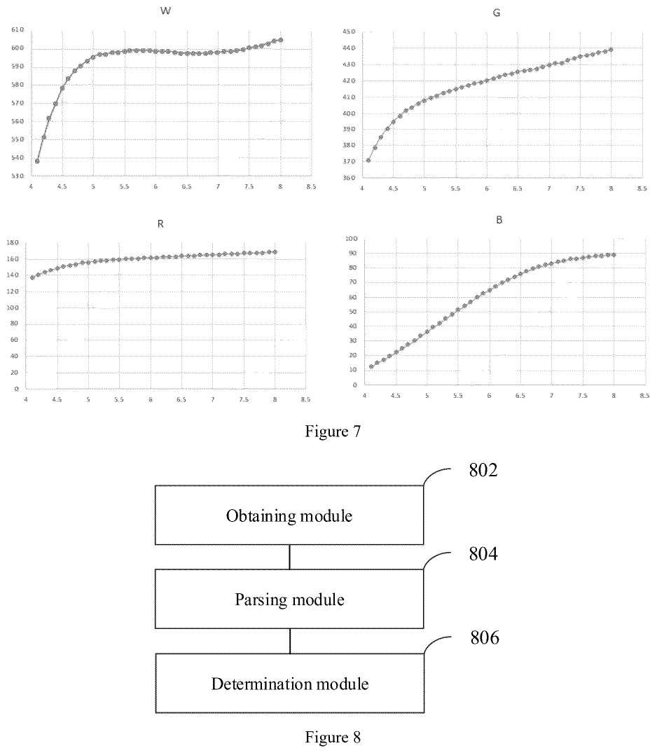

In terms of the display panel of the drive circuit shown in FIG. 1, it is assumed that for the pixel luminance level of BAND1—600 nit, a theoretical common voltage value obtained through simulation calculation is −5.5 V. When this theoretical common voltage value of −5.5 V is directly determined as the target common voltage during the OTP process operation, as can be seen from FIG. 7, the model trends of the R, G, and B color sub-pixels exhibit a noticeable difference. For the R color sub-pixels, the monochromatic luminance value of the display panel near-5.5 V remains almost unchanged (about 160 nit), while for the G and B color sub-pixels, the monochromatic luminance value of the display panel near-5.5 V fluctuates significantly. For the G color sub-pixels, the monochromatic luminance value fluctuates between 40.8 nit and 42 nit (estimated value) within a range of −5 V to −6 V. For the B color sub-pixels, the monochromatic luminance value fluctuates more significantly within the range of −5 V to −6 V, specifically between 38 nit and 78 nit (estimated value). That is, for the R color sub-pixels, the thin-film transistor driving the pixels is close to the saturation region, while for the G and B color sub-pixels, the thin-film transistor driving the pixels is not in the saturation region. This will affect the display image quality of the display panel.

Using the solution provided in this embodiment of the present application, a process of determining the target common voltage is as follows:
1. Based on ELVSS=−5.5 V, the common voltage calibration range is set to −4 to −8 V including-5.5 V. Uniform voltage values are supplied with a step of 0.2 V, and during the OTP process, the monochromatic luminance of the R, G, and B color sub-pixels is simultaneously recorded using a luminance meter, to fit curves shown in FIG. 7.
2. Based on the curves shown in FIG. 7, the final suitable target common voltage ELVSS is selected. In one embodiment, based on the curves shown in FIG. 7, a curve of the ELVSS voltage value versus the monochromatic luminance change rate for the sub-pixels of each color is generated, and a change rate threshold is set, to determine a common voltage A based on the curve of the ELVSS voltage value versus the monochromatic luminance change rate. As such, the voltage A enables the monochromatic luminance change rate for the sub-pixels of each color to be less than the change rate threshold. In this case, A is determined as the target common voltage.
3. For the pixel luminance level of BAND1—600 nit, the target common voltage A is used as a programming configuration condition for the subsequent OTP process operation.
4. For other pixel luminance levels, the above actions may be repeated to find suitable ELVSS voltages B, C . . . , to perform the process operation for the other levels using the ELVSS voltages B, C . . .

It should be noted that the target common voltage corresponding to each pixel luminance level may be determined first, and then the OTP process operation may be performed in a unified manner. The specific order of performing the OTP process is not limited in this embodiment of the present application.

The present application further provides another data processing method.

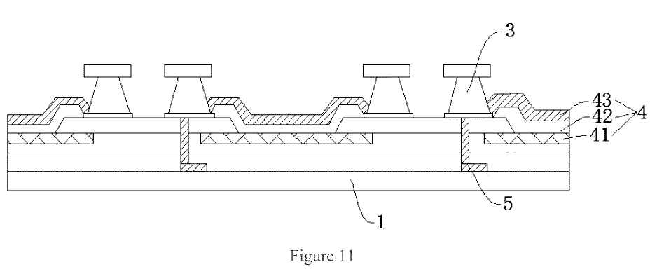

Referring to FIG. 10, The method includes the following steps:
Step 301: Obtain a first mapping relationship between a common voltage corresponding to the sub-pixels of each color and a monochromatic luminance value, and sub-pixels of each color in the display panel are individually lit to cause the display panel to present different monochromatic images;
Step 302: Parse the first mapping relationship to obtain a second mapping relationship between the common voltage corresponding to the sub-pixels of each color and a monochromatic luminance change rate, the monochromatic luminance change rate representing a speed at which the monochromatic luminance value changes with the common voltage; and
Step 303: Determine a target common voltage corresponding to the sub-pixels of each color based on the second mapping relationship to power the sub-pixels of each color in the display panel with the target common voltage corresponding to the sub-pixels of each color, where a monochromatic luminance change rate at sub-pixels of a single color that corresponds to the target common voltage is less than a preset change rate threshold corresponding to the sub-pixels of the single color.

In the above solution of the present application, the display panel includes sub-pixels of colors, such as R color sub-pixels, G color sub-pixels, and B color sub-pixels, and respective common voltages are correspondingly set for the sub-pixels of the colors. That is, in the display panel in the embodiments of the present application, the common voltages among the sub-pixels of the colors are independent of each other.

Referring to FIG. 11, FIG. 11 is a schematic diagram of a display panel structure applicable to the another data processing method provided in the present application, The display panel may include:
a substrate1;
an isolation structure3 located on a side of the substrate, the isolation structure3 enclosing an isolation opening, adjacent isolation structures3 being insulated from each other;
a light-emitting unit4 located within the isolation opening, the light-emitting unit4 including an anode41, a light-emitting functional layer42, and a cathode43 arranged in sequence, at least part of the cathode43 being coupled with the isolation structure3;
and an auxiliary electrode5 close to a side of the substrate, adjacent auxiliary electrodes being insulated from each other, at least part of the isolation structure3 being coupled with the auxiliary electrode5, and the auxiliary electrode5 is configured to transmit a corresponding common voltage to the cathode43 of the light-emitting unit4, and an orthographic projection of the isolation structure3 on the substrate overlaps an orthographic projection of the auxiliary electrode5 on the substrate.

The obtaining a first mapping relationship between a common voltage to the sub-pixels of each color and a monochromatic luminance value of the display panel includes:
determining, for different display modes of the display panel, a theoretical common voltage value to the sub-pixels of each color and determining a common voltage calibration range based on the theoretical common voltage value to the sub-pixels of each color; and
selecting and determining one of the display modes as a current display mode, and in the current display mode, and sub-pixels of each color in the display panel are individually lit to cause the display panel to present different monochromatic images, obtaining the first mapping relationship between the common voltage corresponding to the sub-pixels of each color and a monochromatic luminance value within the common voltage calibration range corresponding to the sub-pixels of each color; and
determining a target common voltage corresponding to the sub-pixels of each color based on the second mapping relationship to power the sub-pixels of each color in the display panel with the target common voltage corresponding to the sub-pixels of each color includes:
Determining the target common voltage corresponding to the sub-pixels of each color within the common voltage calibration range based on the second mapping relationship to power the sub-pixels of each color.

The first mapping relationship and the second mapping relationship are each represented in the form of a curve; and the obtaining the first mapping relationship between the common voltage corresponding to the sub-pixels of each color and a monochromatic luminance value within the common voltage calibration range corresponding to the sub-pixels of each color includes:
performing voltage value sampling within the common voltage calibration range according to a preset voltage sampling rule to obtain sampled common voltages corresponding to the sub-pixels of each color;
obtaining, for each sampled common voltage corresponding to the sub-pixels of each color, a monochromatic luminance values for the sub-pixels of each color at each sampled common voltage; and
Performing curve fitting based on each sampled common voltage and the monochromatic luminance value for the sub-pixels of each color to obtain a first curve as the first mapping relationship corresponding to the sub-pixels of each color between the common voltage and the monochromatic luminance value of the display panel.

The first mapping relationship to obtain a second mapping relationship between the common voltage corresponding to the sub-pixels of each color and a monochromatic luminance change rate for the sub-pixels of each color includes:
In the first curve corresponding to the sub-pixels of each color, calculating a the monochromatic luminance change rate at each sampled common voltage based on a voltage difference between two adjacent sampled common voltages and a corresponding monochromatic luminance difference at the two adjacent sampled common voltages;
performing curve fitting based on each sampled common voltage and the monochromatic luminance change rate at each sampled common voltage to obtain a second curve corresponding to the sub-pixels of each color as the second mapping relationship between the common voltage and the monochromatic luminance change rate; and
the determining the target common voltage corresponding to the sub-pixels of each color within the common voltage calibration range based on the second mapping relationship to power the sub-pixels of each color includes:
obtaining a preset change rate threshold corresponding to the sub-pixels of each color;
Determining whether the monochromatic luminance change rate at each sampled common voltage is less than the preset change rate threshold to obtain a determination results as the target common voltage corresponding to the sub-pixels of each color.

Referring to FIG. 8, FIG. 8 is a schematic structural diagram of a data processing apparatus according to an embodiment of the present application. The data processing apparatus of this embodiment includes the following modules:
an obtaining module 802 configured to obtain a first mapping relationship between a common voltage and a monochromatic luminance value of the display panel, and sub-pixels of each color in the display panel are individually lit to cause the display panel to present different monochromatic images;
a parsing module 804 configured to parse the first mapping relationship to obtain a second mapping relationship between the common voltage and a monochromatic luminance change rate for the sub-pixels of each color, the monochromatic luminance change rate representing a speed at which the monochromatic luminance value changes with the common voltage; and
a determination module 806 configured to determine a target common voltage based on the second mapping relationship to power the display panel with the target common voltage, where the monochromatic luminance change rate at the target common voltage is less than a preset change rate threshold.

In some embodiments, the obtaining module 802 is specifically configured to: determine, for display modes of the display panel, a theoretical common voltage value of the display panel and determine a common voltage calibration range based on the theoretical common voltage value; and select and determine one of the display modes as a current display mode, and in the current display mode, in the case where the sub-pixels of each color in the display panel are individually lit, obtain the first mapping relationship between the common voltage and the monochromatic luminance value of the display panel within the common voltage calibration range.

The determination module 806 is specifically configured to: determine the target common voltage within the common voltage calibration range based on the second mapping relationship, to power the display panel with the target common voltage.

In one embodiment, the target common voltage is stored in the display panel through a programming action.

In some embodiments, the first mapping relationship and the second mapping relationship are each represented in the form of a curve. The obtaining module 802 is specifically configured to: perform voltage value sampling within the common voltage calibration range according to a preset voltage sampling rule to obtain sampled common voltages; obtain, for each sampled common voltage, a monochromatic luminance value for the sub-pixels of each color at each sampled common voltage; and perform curve fitting based on each sampled common voltage and the monochromatic luminance value for the sub-pixels of each color to obtain a first curve between the common voltage and the monochromatic luminance value of the display panel.

In some embodiments, the parsing module 804 is specifically configured to: calculate a monochromatic luminance change rate at each sampled common voltage based on a voltage difference between two adjacent sampled common voltages and a monochromatic luminance difference corresponding to the two adjacent sampled common voltages; and determine a mapping relationship between each sampled common voltage and the monochromatic luminance change rate corresponding to each sampled common voltage as the second mapping relationship between the common voltage and the monochromatic luminance change rate.

The determination module 806 is specifically configured to: obtain a preset change rate threshold corresponding to sub-pixels of each color; and determine whether the monochromatic luminance change rate at each sampled common voltage is less than the preset change rate threshold, and determining the target common voltage from each sampled common voltage based on a determination result.

In some embodiments, the display panel has display modes, and any of the display modes has pixel luminance levels of the display panel. For the different pixel luminance levels in the display mode, the step of determining a theoretical common voltage value of the display panel and determining a common voltage calibration range based on the theoretical common voltage value is separately performed, until a target common voltage for each pixel luminance level in each display mode is determined.

In some embodiments, the display panel has display modes, and any of the display modes has pixel luminance levels of the display panel. When performing, for the display modes of the display panel, the step of determining the theoretical common voltage value of the display panel and determining the common voltage calibration range based on the theoretical common voltage value, the obtaining module 802 is specifically configured to: select a reference pixel luminance level from the pixel luminance levels of the display panel; for the reference pixel luminance level, perform the operation of determining a theoretical common voltage value of the display panel and determining a common voltage calibration range based on the theoretical common voltage value, until a target common voltage for the reference pixel luminance level is determined; and calculate target common voltages for remaining levels of the pixel luminance levels based on the target common voltage for the reference pixel luminance level and an association relationship between target common voltages corresponding to different pixel luminance levels.

In some embodiments, when performing the step of calculating the target common voltage for the remaining level of the pixel luminance levels based on the target common voltage for the reference pixel luminance level and the association relationship between the target common voltages corresponding to different pixel luminance levels, the obtaining module 802 is specifically configured to: for the remaining levels of the pixel luminance levels of the display panel, determine a theoretical common voltage value of the display panel corresponding to each remaining level; calculate a voltage difference between the theoretical common voltage value corresponding to the remaining level and a theoretical common voltage value of the display panel corresponding to the reference pixel luminance level; and determine the target common voltage for the remaining level based on the target common voltage for the reference pixel luminance level and each voltage difference.

In some embodiments, when performing a step of determining a theoretical common voltage value of the display panel for each pixel luminance level, the obtaining module 802 is specifically configured to: construct a simulation model corresponding to the display panel; perform a parameter assignment operation on the simulation model based on a pixel luminance value corresponding to each pixel luminance level and a material property of a light-emitting layer of the display panel; and perform simulation calculation based on the simulation model subjected to parameter assignment, to obtain the theoretical common voltage value corresponding to each pixel luminance level.

In some embodiments, the data processing apparatus further includes:
a warning module configured to output display performance warning information when no target common voltage satisfying a requirement exists within the common voltage calibration range based on the second mapping relationship.

In some embodiments, the determination module 806 is specifically configured to: determine candidate common voltages based on the second mapping relationship, where each monochromatic luminance change rate at the candidate common voltage is less than the preset change rate threshold; and determine the candidate common voltage having a minimum voltage value as the target common voltage.

In some embodiments, the preset change rate threshold is correspondingly set for the sub-pixels of each color; and a monochromatic luminance change rate corresponding to the target common voltage for sub-pixels of a single color is less than a preset change rate threshold for the sub-pixels of the single color.

In some embodiments, the preset voltage sampling rule includes: performing voltage value sampling with a preset step within the common voltage calibration range.

The data processing apparatus of this embodiment is configured to implement the corresponding data processing method in the embodiments described above, and has the beneficial effects of the corresponding method embodiments, which are not described in detail herein again. In addition, for the implementation of the function of each module in the data processing apparatus of this embodiment, reference may be made to the description of the corresponding part in the method embodiments described above, which is not described in detail herein again.

An embodiment of the present application further provides a display apparatus. The display apparatus includes: a display panel, where a one-time programming action is performed on the display panel after power is supplied with the target common voltage obtained according to the data processing method embodiment described above.

An embodiment of the present application further provides a display terminal. The display terminal includes a terminal device body and a display apparatus disposed on the terminal device body. The display apparatus may be the display apparatus described above.

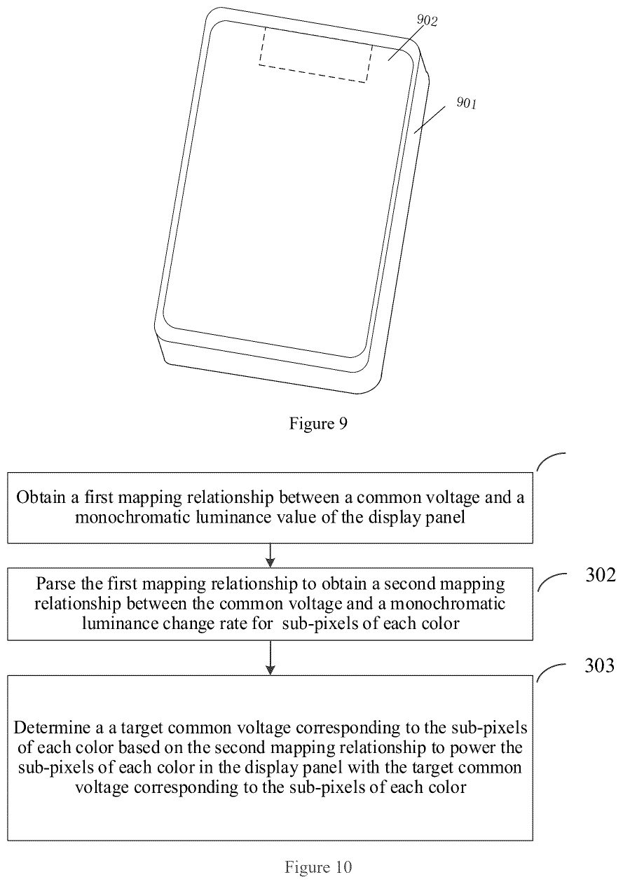

An exemplary display terminal is shown in FIG. 9, which includes a terminal device body 901 and a display panel 902. The display panel 902 is disposed on the terminal device body 901 and is electrically connected to the terminal device body 901. The display panel 902 is the display panel in the embodiment described above and is configured to display a static image or a dynamic image.

For example, the display terminal may be implemented in the form of various electronic devices such as a mobile phone, a tablet computer, a handheld computer, and a PAD.

An embodiment of the present application further provides a computer storage medium having a computer program stored thereon, the program, when executed by a processor, causing the method described in any of the method embodiments described above to be implemented. The computer storage medium includes, but is not limited to: a compact disc read-only memory (CD-ROM), a random access memory (RAM), a floppy disk, a hard disk, a magneto-optical disk, etc.

An embodiment of the present application further provides a computer program product including computer instructions that instruct a computing device to perform operations corresponding to any method in the method embodiments described above.

The units and method steps of various examples described in connection with the embodiments disclosed in the present application may be implemented in electronic hardware or a combination of computer software and electronic hardware. Whether these functions are performed in hardware or software depends on specific applications and design constraint conditions of the embodiments. Different methods for each specific application may be used to implement the described functions, but such implementation should not be considered as falling out of the scope of the embodiments of the present application.

It should be noted that in the present application, the term “include”, “include” or any other variant thereof is intended to cover non-exclusive inclusion, and a process, method, article, or apparatus that includes a series of elements not only includes these elements, but also includes other elements not explicitly listed, or elements that are inherent to such a process, method, article, or apparatus. In the absence of more restrictions, an element defined by a phrase “including one . . . ” does not exclude the presence of other identical elements in a process, method, article, or apparatus that includes the element.

The sequence numbers of the above embodiments of the present application are only for description, and do not represent the superiority or inferiority of the embodiments.

The method disclosed in the method embodiments provided in the present application may be randomly combined without conflict to obtain a new method embodiment.

The features disclosed in the product embodiments provided in the present application may be randomly combined without conflict to obtain a new product embodiment.

The features disclosed in the method or device embodiments provided in the present application may be randomly combined without conflict to obtain a new method embodiment or device embodiment.

The foregoing embodiments are merely used to illustrate the embodiments of the present application, and are not intended to limit the embodiments of the present application. Various modifications and variations without departing from the spirit and scope of the present application. Therefore, all equivalent embodiments also fall within the scope of the embodiments of the present application, the scope of patent protection of the embodiments of the present application shall be defined by the claims.

What is claimed is:

1. A data processing method, comprising:
obtaining a first mapping relationship between a common voltage and a monochromatic luminance value of a display panel, wherein a plurality of sub-pixels of each color in the display panel are individually lit to cause the display panel to present a plurality of different monochromatic images;
parsing the first mapping relationship to obtain a second mapping relationship between the common voltage and a monochromatic luminance change rate for the sub-pixels of each color, the monochromatic luminance change rate representing a speed at which the monochromatic luminance value changes with the common voltage; and
determining a target common voltage based on the second mapping relationship to power the display panel with the target common voltage, wherein the monochromatic luminance change rate for the sub-pixels of each color at the target common voltage is less than a preset change rate threshold.

2. The method according to claim 1, wherein the obtaining a first mapping relationship between a common voltage and a monochromatic luminance value of the display panel comprises:
determining, for different display modes of the display panel, a theoretical common voltage value of the display panel and determining a common voltage calibration range based on the theoretical common voltage value; and
selecting and determining one of the display modes as a current display mode, and in the current display mode, wherein a plurality of sub-pixels of each color in the display panel are individually lit to cause the display panel to present a plurality of different monochromatic images, obtaining the first mapping relationship between the common voltage and the monochromatic luminance value of the display panel within the common voltage calibration range; and
the determining a target common voltage based on the second mapping relationship to power the display panel with the target common voltage comprises:
determining the target common voltage within the common voltage calibration range based on the second mapping relationship, to power the display panel with the target common voltage.

3. The method according to claim 1, wherein the target common voltage is stored in the display panel through a programming action.

4. The method according to claim 2, wherein the first mapping relationship and the second mapping relationship are each represented in the form of a curve; and the obtaining the first mapping relationship between the common voltage and the monochromatic luminance value of the display panel within the common voltage calibration range comprises:
performing voltage value sampling within the common voltage calibration range according to a preset voltage sampling rule to obtain a plurality of sampled common voltages;
obtaining, for each sampled common voltage, a monochromatic luminance value for the sub-pixels of each color at each sampled common voltage; and
performing curve fitting based on each sampled common voltage and the monochromatic luminance value for the sub-pixels of each color to obtain a first curve as the first mapping relationship between the common voltage and the monochromatic luminance value of the display panel.

5. The method according to claim 4, wherein the parsing the first mapping relationship to obtain a second mapping relationship between the common voltage and a monochromatic luminance change rate for the sub-pixels of each color comprises:
in the first curve, calculating the monochromatic luminance change rate at each sampled common voltage based on a voltage difference between two adjacent sampled common voltages and a corresponding monochromatic luminance difference at the two adjacent sampled common voltages; and
performing curve fitting based on each sampled common voltage and the monochromatic luminance change rate at each sampled common voltage to obtain a second curve as the second mapping relationship between the common voltage and the monochromatic luminance change rate; and
the determining the target common voltage within the common voltage calibration range based on the second mapping relationship comprises:
obtaining a preset change rate threshold corresponding to the sub-pixels of each color; and
determining whether the monochromatic luminance change rate at each sampled common voltage is less than the preset change rate threshold to obtain a plurality of determination results, and determining the target common voltage from each sampled common voltage based on the determination results.

6. The method according to claim 2, wherein the display panel comprises a plurality of display modes, and any of the display modes comprises a plurality of pixel luminance levels of the display panel; and
for the different pixel luminance levels in the display mode, the step of determining a theoretical common voltage value of the display panel and determining a common voltage calibration range based on the theoretical common voltage value is performed, until a target common voltage for each pixel luminance level in each display mode is determined.

7. The method according to claim 2, wherein the display panel comprises a plurality of display modes, and any of the display modes comprises a plurality of pixel luminance levels of the display panel; and
the determining, for different display modes of the display panel, a theoretical common voltage value of the display panel and determining a common voltage calibration range based on the theoretical common voltage value comprises:
selecting a reference pixel luminance level from the plurality of pixel luminance levels of the display panel;
for the reference pixel luminance level, performing the step of determining a theoretical common voltage value of the display panel and determining a common voltage calibration range based on the theoretical common voltage value, until a target common voltage for the reference pixel luminance level is determined; and
calculating a plurality of target common voltages for remaining levels of the plurality of pixel luminance levels based on the target common voltage for the reference pixel luminance level and an association relationship between target common voltages corresponding to different pixel luminance levels.

8. The method according to claim 7, wherein the calculating target common voltages for remaining levels of the plurality of pixel luminance levels based on the target common voltage for the reference pixel luminance level and an association relationship between target common voltages corresponding to different pixel luminance levels comprises:
for the remaining levels of the plurality of pixel luminance levels of the display panel, determining each of the remaining levels corresponds to a first theoretical common voltage value, and the reference pixel luminance level corresponds to a second theoretical voltage value;
calculating a theoretical voltage difference between the first theoretical common voltage value and the second theoretical voltage value;
calculating a target common voltage corresponding to each of the remaining levels based on the target common voltage of the reference pixel luminance level and the theoretical voltage difference corresponding to each of the remaining levels.

9. The method according to claim 6, wherein a process of determining a theoretical common voltage value of the display panel for each pixel luminance level comprises:
constructing a simulation model corresponding to the display panel;
performing a parameter assignment operation on the simulation model based on a pixel luminance value corresponding to each pixel luminance level and a plurality of material properties of light-emitting layers of the display panel; and
performing simulation calculation based on the simulation model subjected to parameter assignment, to obtain the theoretical common voltage value corresponding to each pixel luminance level.

10. The method according to claim 2, further comprising:
outputting display performance warning information when no target common voltage satisfying a requirement exists within the common voltage calibration range based on the second mapping relationship.

11. The method according to claim 1, wherein the determining a target common voltage based on the second mapping relationship comprises:
determining a plurality of candidate common voltages based on the second mapping relationship, wherein each monochromatic luminance change rate at the candidate common voltage is less than the preset change rate threshold; and
determining the candidate common voltage having a minimum voltage value as the target common voltage.

12. The method according to claim 1, wherein the preset change rate threshold is correspondingly set for the sub-pixels of each color; and the monochromatic luminance change rate at the target common voltage for sub-pixels of a single color is less than a preset change rate threshold corresponding to the sub-pixels of the single color.

13. The method according to claim 4, wherein the preset voltage sampling rule comprises:
performing voltage value sampling with a preset step within the common voltage calibration range.

14. The data processing method according to claim 1, wherein the display panel comprises:
a substrate;
an isolation structure located on a side of the substrate, the isolation structure enclosing a plurality of isolation openings; and
a light-emitting unit located within the isolation opening, the light-emitting unit comprises an anode, a light-emitting functional layer, and a cathode arranged in sequence, at least part of the cathode being coupled with the isolation structure, wherein the isolation structure is a conductive material for transmitting the common voltage to the cathode.

15. A data processing method, comprising:
obtaining a first mapping relationship between a common voltage corresponding to the sub-pixels of each color and a monochromatic luminance value, wherein a plurality of sub-pixels of each color in the display panel are individually lit to cause the display panel to present a plurality of different monochromatic images;
parsing the first mapping relationship to obtain a second mapping relationship between the common voltage corresponding to the sub-pixels of each color and a monochromatic luminance change rate, the monochromatic luminance change rate representing a speed at which the monochromatic luminance value changes with the common voltage; and
determining a target common voltage corresponding to the sub-pixels of each color based on the second mapping relationship to power the sub-pixels of each color in the display panel with the target common voltage corresponding to the sub-pixels of each color, wherein a monochromatic luminance change rate at sub-pixels of a single color that corresponds to the target common voltage is less than a preset change rate threshold corresponding to the sub-pixels of the single color.

16. The data processing method according to claim 15, wherein the display panel comprises:
a substrate;
an isolation structure located on a side of the substrate, the isolation structure enclosing a plurality of isolation openings;
a light-emitting unit located within the isolation opening, the light-emitting unit comprises an anode, a light-emitting functional layer, and a cathode arranged in sequence, at least part of the cathode being coupled with the isolation structure; and
an auxiliary electrode close to a side of the substrate, adjacent auxiliary electrodes being insulated from each other, at least part of the cathode of the light-emitting unit being coupled with the auxiliary electrode,
wherein the auxiliary electrode is configured to transmit a corresponding common voltage to the cathode of the light-emitting unit.

17. The data processing method according to claim 16, wherein the obtaining a first mapping relationship between a common voltage to the sub-pixels of each color and a monochromatic luminance value of the display panel comprises:
determining, for different display modes of the display panel, a theoretical common voltage value to the sub-pixels of each color and determining a common voltage calibration range based on the theoretical common voltage value to the sub-pixels of each color; and
selecting and determining one of the display modes as a current display mode, and in the current display mode, wherein a plurality of sub-pixels of each color in the display panel are individually lit to cause the display panel to present a plurality of different monochromatic images, obtaining the first mapping relationship between the common voltage corresponding to the sub-pixels of each color and a monochromatic luminance value within the common voltage calibration range corresponding to the sub-pixels of each color; and
determining a target common voltage corresponding to the sub-pixels of each color based on the second mapping relationship to power the sub-pixels of each color in the display panel with the target common voltage corresponding to the sub-pixels of each color comprises:
determining the target common voltage corresponding to the sub-pixels of each color within the common voltage calibration range based on the second mapping relationship to power the sub-pixels of each color.

18. The data processing method according to claim 17, wherein the first mapping relationship and the second mapping relationship are each represented in the form of a curve; and the obtaining the first mapping relationship between the common voltage corresponding to the sub-pixels of each color and a monochromatic luminance value within the common voltage calibration range corresponding to the sub-pixels of each color comprises:
performing voltage value sampling within the common voltage calibration range according to a preset voltage sampling rule to obtain a plurality of sampled common voltages corresponding to the sub-pixels of each color;
obtaining, for each sampled common voltage corresponding to the sub-pixels of each color, a monochromatic luminance values for the sub-pixels of each color at each sampled common voltage; and
performing curve fitting based on each sampled common voltage and the monochromatic luminance value for the sub-pixels of each color to obtain a first curve as the first mapping relationship corresponding to the sub-pixels of each color between the common voltage and the monochromatic luminance value of the display panel.

19. The data processing method according to claim 18, wherein parsing the first mapping relationship to obtain a second mapping relationship between the common voltage corresponding to the sub-pixels of each color and a monochromatic luminance change rate for the sub-pixels of each color comprises:
in the first curve corresponding to the sub-pixels of each color, calculating a the monochromatic luminance change rate at each sampled common voltage based on a voltage difference between two adjacent sampled common voltages and a corresponding monochromatic luminance difference at the two adjacent sampled common voltages;
performing curve fitting based on each sampled common voltage and the monochromatic luminance change rate at each sampled common voltage to obtain a second curve corresponding to the sub-pixels of each color as the second mapping relationship between the common voltage and the monochromatic luminance change rate; and
the determining the target common voltage corresponding to the sub-pixels of each color within the common voltage calibration range based on the second mapping relationship to power the sub-pixels of each color comprises:
obtaining a preset change rate threshold corresponding to the sub-pixels of each color; and
determining whether the monochromatic luminance change rate at each sampled common voltage is less than the preset change rate threshold to obtain a determination results as the target common voltage corresponding to the sub-pixels of each color.

20. A data processing apparatus, comprising:
an obtaining module configured to obtain a first mapping relationship between a common voltage and a monochromatic luminance value of a display panel, wherein a plurality of sub-pixels of each color in the display panel are individually lit to cause the display panel to present a plurality of different monochromatic images;
a parsing module configured to parse the first mapping relationship to obtain a second mapping relationship between the common voltage and a monochromatic luminance change rate for the sub-pixels of each color, the monochromatic luminance change rate representing a speed at which the monochromatic luminance value changes with the common voltage; and
a determination module configured to determine a target common voltage based on the second mapping relationship to power the display panel with the target common voltage, wherein the monochromatic luminance change rate at the target common voltage is less than a preset change rate threshold.
